(19) United States
(12) Patent Application Publication
(10) Pub. No.: US 2015/0179681 A1
(43) Pub. Date: Jun. 25, 2015

(54) SEMICONDUCTOR DEVICE, METHOD OF MANUFACTURING THE SAME, DISPLAY UNIT, AND ELECTRONIC APPARATUS

(71) Applicant: Sony Corporation, Tokyo (JP)

(72) Inventor: Ayumu Sato, Tokyo (JP)

(21) Appl. No.: 14/553,219

(22) Filed: Nov. 25, 2014

(30) Foreign Application Priority Data
Dec. 24, 2013 (JP) 2013-265553

(51) Int. Cl. H01L 27/12

(52) U.S. Cl. CPC H01L 27/1255; H01L 27/1225; H01L 27/1288; H01L 27/127

(57) ABSTRACT

A semiconductor device includes: a transistor having an oxide semiconductor film; and a retention capacitor having a first conductive film and a second conductive film, the first conductive film containing an oxide material and being in contact with the oxide semiconductor film, and the second conductive film facing the first conductive film with an insulating film in between.

### CROSS REFERENCE TO RELATED APPLICATIONS

This application claims the benefit of Japanese Priority Patent Application JP 2013-265553 filed Dec. 24, 2013, the entire contents of which are incorporated herein by reference.

### BACKGROUND

The present disclosure relates to a semiconductor device using an oxide semiconductor, a method of manufacturing the semiconductor device, and a display unit and an electronic apparatus that include the semiconductor device.

In a liquid crystal display unit and an organic electroluminescence (EL) display unit of an active drive method, a thin film transistor (TFT) is used as a driving element, and charges corresponding to a signal voltage for picture writing are retained in a retention capacitor. However, when a parasitic capacitance generated in an intersection region between a gate electrode and a source-drain electrode of the TFT is increased, the signal voltage is varied, which may cause deterioration in image quality.

In particular, in the organic EL display unit, when the parasitic capacitance is large, it is necessary to increase the retention capacitance. Therefore, a ratio occupied by wirings and the like is increased depending on a layout of pixels. As a result, probability of short-circuit between wirings and the like is increased, which causes deterioration in manufacturing yield.

Therefore, in the TFT using an oxide semiconductor such as zinc oxide (ZnO) and indium gallium zinc oxide (IGZO) for a channel, a method of reducing the parasitic capacitance in the intersection region between the gate electrode and the source-drain electrode has been proposed (for example, Japanese Unexamined Patent Application Publication Nos. 2012-212077 and 2013-183111, and “Self-aligned top-gate amorphous gallium indium zinc oxide thin film transistors”, J. Park, et al., Applied Physics Letters, American Institute of Physics, 2008, No. 93, 053501, and “Improved Amorphous In—Ga—Zn—O TFTs”, R. Hayashi, et al., SID 08 DIGEST, 2008, 42. 1, pp. 621-624).

In Japanese Unexamined Patent Application Publication Nos. 2012-212077 and 2013-183111, and “Self-aligned top-gate amorphous gallium indium zinc oxide thin film transistors”, J. Park, et al., Applied Physics Letters, American Institute of Physics, 2008, No. 93, 053501, a top-gate type TFT formed by a method in which, after a gate insulating film and a gate electrode are provided at the same position in a planner view on a channel region of an oxide semiconductor film, a region exposed from the gate electrode and the gate insulating film of the oxide semiconductor film is decreased in resistance to form source-drain regions, namely, self-alignment is described. On the other hand, in “Improved Amorphous In—Ga—Zn—O TFTs”, R. Hayashi, et al., SID 08 DIGEST, 2008, 42. 1, pp. 621-624 discloses a bottom-gate type TFT having a self-alignment structure, and in this TFT, source-drain regions are formed in an oxide semiconductor film by back-surface exposure using a gate electrode as a mask.

A semiconductor device to drive a display element includes a retention capacitor together with a transistor using such an oxide semiconductor film, on a substrate. The retention capacitor may desirably retain a desired capacitance stably. However, when the retention capacitor is configured using the oxide semiconductor film as one of electrodes of the retention capacitor, the value of the retention capacitance easily varies in response to the magnitude of an applied voltage. In other words, an issue of voltage dependency arises.

In Japanese Unexamined Patent Application Publication No. 2012-212077, a method in which a metal film such as titanium, molybdenum, and aluminum is provided in a formation region of the retention capacitor is proposed in order to solve the issue of the voltage dependency. In such a retention capacitor, the metal film functions as one of the electrodes.

### SUMMARY

However, in such a semiconductor device, the oxide semiconductor film is shared by the retention capacitor and the transistor, and the metal film is in contact with the oxide semiconductor film. Therefore, the metal film may influence the oxide semiconductor film, which may degrade transfer characteristics of the transistor.

It is desirable to provide a semiconductor device capable of retaining a desired capacitance in a retention capacitor stably and maintaining transfer characteristics of a transistor, a method of manufacturing the semiconductor device, and a display unit and an electronic apparatus each provided with the semiconductor device.

According to an embodiment of the technology, there is provided a semiconductor device including: a transistor having an oxide semiconductor film; and a retention capacitor having a first conductive film and a second conductive film, the first conductive film containing an oxide material and being in contact with the oxide semiconductor film, and the second conductive film facing the first conductive film with an insulating film in between.

According to an embodiment of the technology, there is provided a display unit provided with a plurality of display elements and a semiconductor device configured to drive the display elements. The semiconductor device includes: a transistor having an oxide semiconductor film; and a retention capacitor having a first conductive film and a second conductive film, the first conductive film containing an oxide material and being in contact with the oxide semiconductor film, and the second conductive film facing the first conductive film with an insulating film in between.

According to an embodiment of the technology, there is provided an electronic apparatus provided with a display unit. The display unit is provided with a plurality of display elements and a semiconductor device configured to drive the display elements. The semiconductor device includes: a transistor having an oxide semiconductor film; and a retention capacitor having a first conductive film and a second conductive film, the first conductive film containing an oxide material and being in contact with the oxide semiconductor film, and the second conductive film facing the first conductive film with an insulating film in between.

In the semiconductor device, the display unit, and the electronic apparatus according to the respective embodiments of the technology, the oxide material is contained in the first conductive film that functions as one of electrodes of the retention capacitor. Therefore, oxygen in the oxide semiconductor film is difficult to migrate to the first conductive film.

According to an embodiment of the technology, there is provided a method of manufacturing a semiconductor device. The method includes: forming an oxide semiconductor film; forming a first conductive film, the first conductive film being in contact with the oxide semiconductor film and containing an oxide material; and forming a transistor and a retention capacitor having the first conductive film and a second conductive film, the transistor having a channel region provided in a part of the oxide semiconductor film, and the second conductive film facing the first conductive film with an insulating film in between.

In the method of manufacturing the semiconductor device according to the embodiment of the technology, the first conductive film as one of electrodes of the retention capacitor is formed so as to contain the oxide material. Therefore, oxygen in the oxide semiconductor film is difficult to migrate to the first conductive film.

In the semiconductor device, the method of manufacturing the semiconductor device, and the display unit and the electronic apparatus that include the semiconductor device according to the respective embodiments of the technology, instead of the oxide semiconductor film, the first conductive film is used as one of the electrodes of the retention capacitor. Therefore, it is possible to retain a desired capacitance stably irrespective of the magnitude of the applied voltage. Moreover, since the first conductive film contains the oxide material, it is possible to suppress influence of the first conductive film on the oxide semiconductor film. Consequently, it is possible to suppress degradation of the transfer characteristics of the transistor. Incidentally, effects described here are non-limiting. Effects achieved by the technology may be one or more of effects described in the present disclosure.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a sectional diagram illustrating a structure of a display unit according to an embodiment of the technology.

FIG. 2 is a diagram illustrating a structure of a retention capacitor illustrated in FIG. 1.

FIG. 3 is a diagram illustrating another example of the structure of the retention capacitor illustrated in FIG. 1.

FIG. 4 is a diagram illustrating an entire configuration including peripheral circuits of the display unit illustrated in FIG. 1.

FIG. 5 is a diagram illustrating a circuit configuration of a pixel illustrated in FIG. 4.

FIG. 6A is a sectional diagram illustrating a method of manufacturing the display unit illustrated in FIG. 1 in a process order.

FIG. 6B is a sectional diagram illustrating a process following the process of FIG. 6A.

FIG. 6C is a sectional diagram illustrating a process following the process of FIG. 6B.

FIG. 6D is a sectional diagram illustrating a process following the process of FIG. 6C.

FIG. 7A is a sectional diagram illustrating a process following the process of FIG. 6D.

FIG. 7B is a sectional diagram illustrating a process following the process of FIG. 7A.

FIG. 7C is a sectional diagram illustrating a process following the process of FIG. 7B.

FIG. 8A is a diagram illustrating hysteresis of transistor characteristics in a display unit in which a metal film is not in contact with an oxide semiconductor film.

FIG. 8B is a diagram illustrating hysteresis of transistor characteristics in the display unit illustrated in FIG. 1.

FIG. 8C is a diagram illustrating hysteresis of transistor characteristics in a display unit in which a metal film is in contact with an oxide semiconductor film.

FIG. 9 is a diagram illustrating relationship between a capacitance of the retention capacitor illustrated in FIG. 1 and an applied voltage.

FIG. 10 is a sectional diagram illustrating another example of the retention capacitor illustrated in FIG. 1.

FIG. 11A is a sectional diagram illustrating a method of manufacturing the retention capacitor illustrated in FIG. 10 in a process order.

FIG. 11B is a sectional diagram illustrating a process following the process of FIG. 11A.

FIG. 12 is a sectional diagram illustrating a structure of a display unit according to a modification 1.

FIG. 13 is a sectional diagram illustrating a structure of a display unit according to a modification 2.

FIG. 14 is a plan view illustrating a schematic configuration of a module including the display unit according to any of the above-described embodiment and the like.

FIG. 15 is a perspective view illustrating an appearance of an application example 1.

FIG. 16 is a perspective view illustrating an appearance of an application example 2.

### DETAILED DESCRIPTION

Hereinafter, an embodiment of the technology will be described in detail with reference to drawings. Note that description will be given in the following order.

1. Embodiment (Organic EL display unit)
2. Modification 1 (Liquid crystal display unit)
3. Modification 2 (Electronic paper)

### 4. Application Examples

### Embodiment

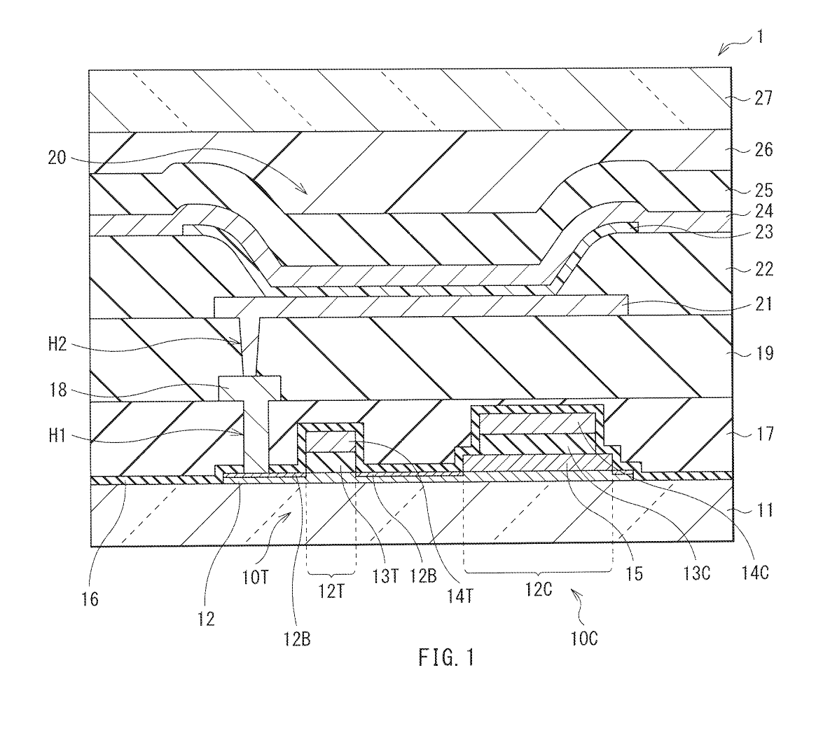

FIG. 1 illustrates a sectional structure of a display unit 1 according to an embodiment of the technology. The display unit 1 is an active matrix organic electroluminescence (EL) display unit, and includes a plurality of transistors 10T and a plurality of organic EL elements 20. The plurality of transistors 10T each have an oxide semiconductor film 12, and the plurality of organic EL elements 20 are driven by the respective transistors 10T. FIG. 1 illustrates a region (a sub-pixel) corresponding to one transistor 10T and one organic EL element 20.

The display unit 1 has a retention capacitor 10C together with the transistor 10T on a substrate 11, and the organic EL element 20 is provided on the transistor 10T and the retention capacitor 10C with a planarization film 19 in between. The transistor 10T and the retention capacitor 10C correspond to a specific but non-limiting example of “semiconductor device” in the technology. The transistor 10T is a TFT of staggered structure (top-gate type) including the substrate 11, the oxide semiconductor film 12, a gate insulating film 13T, and a gate electrode 14T in this order. The oxide semiconductor film 12 and the gate electrode 14T are covered with an interlayer insulating film 17. A source-drain electrode 18 of the transistor 10T is electrically connected to the oxide semiconductor film 12 through a connection hole H1 of the interlayer insulating film 17.

### (Transistor 10T)

For example, the substrate 11 may be formed of a plate member such as quartz, glass, silicon, and a resin (plastic) film. An inexpensive resin film may be used because the oxide semiconductor film 12 is allowed to be formed without heating the substrate 11 in a sputtering method described later. Examples of resin materials may include, for example, polyethylene terephthalate (PET) and polyethylene naphthalate (PEN). In addition, a metal substrate formed of stainless steel (SUS) or the like may be used according to the purpose.

The oxide semiconductor film 12 is provided in a selective region on the substrate 11, and has a function as an active layer of the transistor 10T. For example, the oxide semiconductor film 12 may contain an oxide of one or more elements of indium (In), gallium (Ga), zinc (Zn), and tin (Sn) as a main component. Specifically, examples of the oxide may include indium tin zinc oxide (ITZO), indium gallium oxide (IGO), indium tin oxide (ITO), aluminum tin zinc oxide (ATZO), and zinc tin oxide (ZTO). Crystalline indium gallium oxide or crystalline aluminum tin zinc oxide (ATZO) may be used. In addition, a material exhibiting higher etching resistance than an oxide conductive film 15 descried later may be preferably used for a predetermined etchant. The oxide semiconductor film 12 may have a thickness (a thickness in a stacked-layer direction (Z direction), hereinafter, simply referred to as a thickness) of, for example, about 50 nm.

The oxide semiconductor film 12 has a channel region 12T opposed to the gate electrode 14T in an upper layer, and a pair of low-resistance regions 12B (source-drain regions). The pair of low-resistance regions 12B is adjacent to the channel region 12T, and has electric resistivity lower than that of the channel region 12T. The low-resistance regions 12B are provided in a part of the thickness direction from a surface (a top surface) of the oxide semiconductor film 12, and for example, may be formed by reacting a metal such as aluminum (Al) with an oxide semiconductor material to diffuse the metal (dopant). The source-drain electrode 18 is electrically connected to the low-resistance region 12B. Providing such low-resistance regions 12B achieves a self-alignment structure of the transistor 10T. Moreover, the low-resistance regions 12B also have a function of stabilizing characteristics of the transistor 10T. In a part configuring the transistor 10T, the top surface (a surface facing the gate electrode 14T) of the oxide semiconductor film 12 is in contact with the gate insulating film 13T.

The gate electrode 14T is provided on the channel region 12T with the gate insulating film 13T in between, and the gate electrode 14T and the gate insulating film 13T have the same shape as each other in a planar view. The gate insulating film 13T may have a thickness of, for example, about 300 nm, and is configured of a single layer film formed of one of a silicon oxide film (SiO), a silicon nitride film (SiN), a silicon oxynitride film (SiON), an aluminum oxide film (A10), and the like, or a stacked layer film formed of two or more thereof. A material hardly reducing the oxide semiconductor film 12, for example, a silicon oxide film or an aluminum oxide film may be preferably used for the gate insulating film 13T.

The gate electrode 14T controls a carrier density in the oxide semiconductor film 12 (the channel region 12T) with use of a gate voltage (Vg) applied to the transistor 10T, and has a function as a wiring supplying potential. For example, the gate electrode 14T may be made of a simple substance formed of one of molybdenum (Mo), titanium (Ti), aluminum, silver (Ag), neodymium (Nd), and copper (Cu), or an alloy thereof. The gate electrode 14T may have a stacked layer structure using a plurality of simple substances or alloys. For example, the gate electrode 14T may be configured by stacking titanium, aluminum, and molybdenum in this order on the oxide semiconductor film 14 side. The gate electrode 14T may be preferably formed of a low-resistance metal such as aluminum and copper. A layer (a barrier layer) made of titanium or molybdenum may be stacked on a layer (a low-resistance layer) made of a low-resistance metal, or an alloy containing a low-resistance metal, for example, an alloy of aluminum and neodymium (Al—Nd) may be used. The gate electrode 14T may be configured of a transparent conductive film such as ITO. The gate electrode 14T may have a thickness of, for example, about 10 nm to about 500 nm.

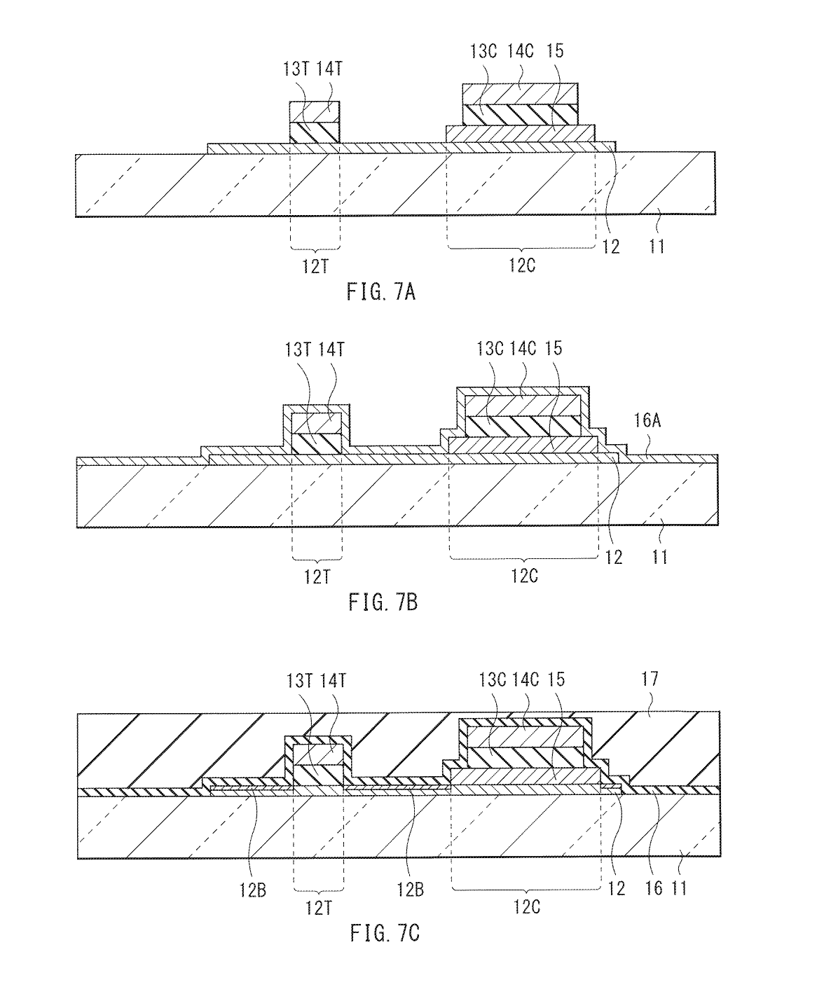

A high-resistance film 16 is provided between the gate electrode 14T and the interlayer insulating film 17 and between the oxide semiconductor film 12 (the low-resistance regions 12B) and the interlayer insulating film 17. The high-resistance film 16 covers end surfaces of the gate electrode 14T, end surfaces of the gate insulating film 13T, and end surfaces of the oxide semiconductor film 12, and also covers the retention capacitor 10C. The high-resistance film 16 is formed in such a manner that a metal film (a metal film 16A in FIG. 7B described later) that is a supply source of a metal to be diffused into the low-resistance regions 12B of the oxide semiconductor film 12 remains as an oxide film in a manufacturing process described later. The high-resistance film 16 is in contact with the low-resistance regions 12B of the oxide semiconductor film 12. Alternatively, the high-resistance film 16 may be formed by further providing an insulating film having high barrier property such as an aluminum oxide film, on the remaining oxide film. The high-resistance film 16 may have a thickness of, for example, about 20 nm or less, and may be formed of titanium oxide, aluminum oxide, indium oxide, tin oxide, or the like. The high-resistance film 16 may be formed by stacking a plurality of oxide films. When an insulating film having high barrier property is stacked on the high-resistance film 16, a total thickness thereof may be, for example, about 50 nm. Such a high-resistance film 16 has a function of reducing influence of oxygen and moisture that change electrical characteristics of the oxide semiconductor film 12 in the transistor 10T, namely, a barrier function, in addition to the above-described process function. Therefore, providing the high-resistance film 16 makes it possible to stabilize the electrical characteristics of the transistor 10T and the retention capacitor 10C, and to further enhance the effect of the interlayer insulating film 17.

The interlayer insulating film 17 is provided on the high-resistance film 16, and similarly to the high-resistance film 16, extends to outside of the oxide semiconductor film 12 to cover the gate electrode 14T and the oxide semiconductor film 12. For example, the interlayer insulating film 17 may be formed of an organic material such as an acrylic resin, polyimide, and siloxane, or an inorganic material such as a silicon oxide film, a silicon nitride film, a silicon oxynitride film, and aluminum oxide. The interlayer insulating film 17 may be formed by stacking such an organic material and such an inorganic material. The interlayer insulating film 17 containing the organic material is allowed to be easily increased in thickness to about 2 μm, for example. The interlayer insulating film 17 increased in thickness in this way is allowed to sufficiently covers level difference between the gate insulating film 13T and the gate electrode 14T to ensure insulation property. Moreover, the interlayer insulating film 17 containing the organic material is allowed to reduce wiring capacity formed by the metal wiring and to increase the display unit 1 in size and in frame rate. Therefore, in the transistor 10T with a self-alignment structure, the interlayer insulating film 17 containing the organic insulating material may be preferably used.

The source-drain electrode 18 is patterned and provided on the interlayer insulating film 17, and is connected to the low-resistance region 12B of the oxide semiconductor film 12 through the connection hole H1 that penetrates through the interlayer insulating film 17 and the high-resistance film 16. The source-drain electrode 18 may be desirably provided at a position other than directly above the gate electrode 14T in order to prevent a parasitic capacitance from being formed in an intersection region between the gate electrode 14T and the source-drain electrode 18. The source-drain electrode 18 may have a thickness of, for example, about 500 nm, and is formed of the metal or the material similar to that of the transparent conductive film described for the above-described gate electrode 14T. The source-drain electrode 18 may also be preferably formed of a low-resistance metal material such as aluminum and copper, and may be preferably a stacked-layer film including a low-resistance layer and a barrier layer. This is because, when the source-drain electrode 18 is configured of such a stacked-layer film, driving with less wiring delay becomes possible. An alloy of aluminum and neodymium may be provided on an uppermost layer of the source-drain electrode 18. This may allow the source-drain electrode 18 to also function as a first electrode (a first electrode 21 described later) of the organic EL element 20, for example.

### (Retention Capacitor 10C)

The retention capacitor 10C is a capacitor that may retain charges in a pixel circuit 50A described later, for example. The retention capacitor 10C is provided on the oxide semiconductor film 12 extending from the transistor 10T, and has an oxide conductive film 15 (a first conductive film), a capacitance insulating film 13C (an insulating film), and a capacitance electrode 14C (a second conductive film) in this order from the oxide semiconductor film 12 side. In other words, in the formation region of the retention capacitor 10C, the oxide conductive film 15 is in contact with the top surface of the oxide semiconductor film 12. The retention capacitor 10C is configured of the oxide conducive film 15 and the capacitance electrode 14C that is opposed to the oxide conductive film 15 with the capacitance insulating film 13C in between. In this way, the oxide conductive film 15 that functions as one of electrodes of the retention capacitor 10C is provided separately from the oxide semiconductor film 12, which makes it possible to retain a desired capacitance stably irrespective of magnitude of the applied voltage.

In the present embodiment, the oxide conductive film 15 contains an oxide material. Although detail will be described later, this suppresses migration of oxygen from the oxide semiconductor film 12 to the oxide conductive film 15, and thus influence of the oxide conductive film 15 to the oxide semiconductor film 12 is suppressed.

The oxide conductive film 15 is formed of an oxide conductive material. A material containing one or more of the metal elements same as the materials of the oxide semiconductor film 12 may be preferably used as the material of the oxide conductive film 15. When the oxide semiconductor film 12 is formed of indium tin zinc oxide (ITZO), indium gallium oxide (IGO), indium tin oxide (ITO), aluminum tin zinc oxide (ATZO), zinc tin oxide (ZTO), or the like, for example, indium gallium zinc oxide (IGZO) or indium zinc oxide (IZO (registered trademark)) may be used for the oxide conductive film 15. The oxide conductive film 15 may have a thickness of, for example, about 20 nm to about 200 nm. The conductivity of the oxide conductive film 15 may be, for example, about 1×10 S/cm to 1×10⁴ S/cm.

Such an oxide conductive film 15 is provided in a selective region on the oxide semiconductor film 12, and the entire bottom surface (a surface opposite to the surface facing the capacitance electrode 14C) is in contact with the oxide semiconductor film 12.

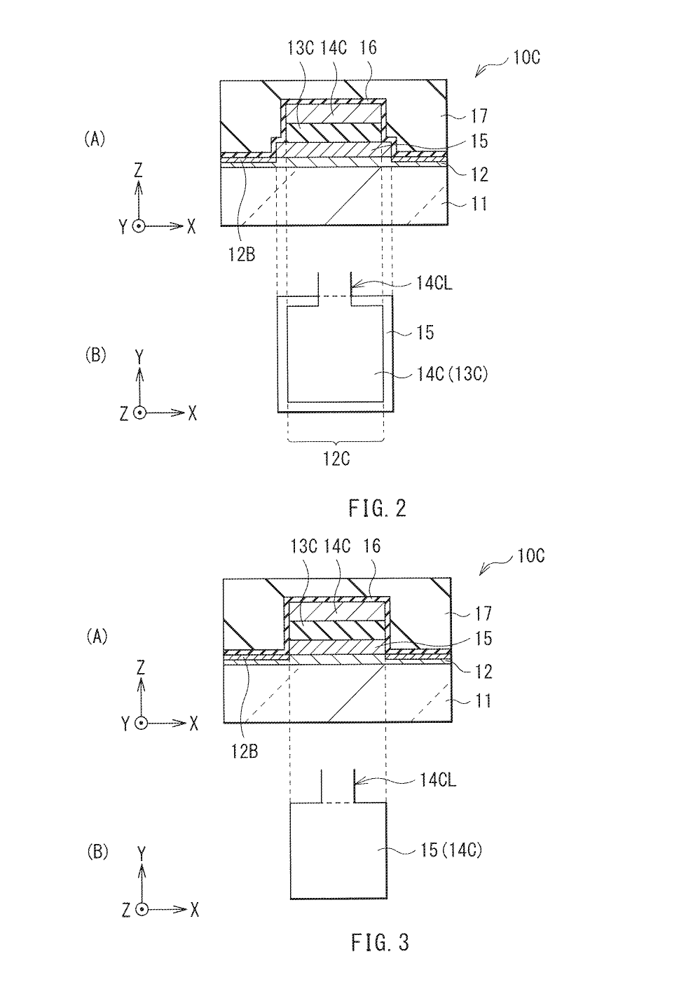

FIG. 2 illustrates a detailed structure of the retention capacitor 10C, where (A) of FIG. 2 illustrates a sectional surface structure of the retention capacitor 10C, and (B) of FIG. 2 illustrates a planar configuration thereof. A planar shape of the oxide conductive film 15 may be, for example, a square shape, and at least a part of peripheral edge of the oxide conductive film 15 is provided outside the peripheral edge of the capacitance electrode 14C. For example, a wiring connection part 14CL extending in one direction may be integrally connected to a part of the outer periphery of the capacitance electrode 14C having a substantially square shape. The wiring connection part 14CL extends to the outside of the peripheral edge of the oxide conductive film 15. On the other hand, in the capacitance electrode 14C in a part other than the wiring connection part 14CL, the oxide conductive film 15 expands to the outside of the capacitance electrode 14C, and an area of the oxide conductive film 15 is larger than that of the capacitance electrode 14C.

As illustrated in FIG. 3, at least a part of the peripheral edge of the oxide conductive film 15 may be overlapped with the peripheral edge of the capacitance electrode 14C. For example, in the capacitance electrode 14C in a part other than the wiring connection part 14CL, the planar shape thereof may be the same as the planar shape of the oxide conductive film 15, and the peripheral edge thereof is overlapped with the peripheral edge of the oxide conductive film 15. (A) of FIG. 3 illustrates a sectional surface structure of the retention capacitor 10C, and (B) of FIG. 3 illustrates a planar configuration thereof.

In the oxide semiconductor film 12, a part in contact with the bottom surface of the oxide conductive film 15 (a contact region 12C) does not have the low-resistance region 12B similarly to the channel region 12T, and electric resistivity of the contact region 12C in the thickness direction is fixed. In other words, the low-resistance region 12B is provided in the oxide semiconductor film 12 other than the channel region 12T and the contact region 12C.

The capacitance insulating film 13C is formed of an inorganic insulating material, which makes it possible to obtain the retention capacitor 10C with large capacitance. For example, the retention insulating film 13C may be formed at the same process as the gate insulating film 13T, and may be formed of the same material with the same thickness as those of the gate insulating film 13T. Moreover, for example, the capacitance electrode 14C may be formed at the same process as the gate electrode 14T, and may be formed of the same material with the same thickness as those of the gate electrode 14T. The capacitance electrode 14C and the capacitance insulating film 13C have the same shape as each other in a planar view, and are stacked at the same position on the substrate 11. The capacitance insulating film 13C and the gate insulating film 13T may be formed of different materials with different thicknesses at different processes from each other. The capacitance electrode 14C and the gate electrode 14T may be formed of different materials with different thicknesses at different processes from each other.

The organic EL element 20 is provided on the planarization film 19 (FIG. 1). The organic EL element 20 includes the first electrode 21, a pixel separation film 22, an organic layer 23, and a second electrode 24 in this order from the planarization film 19 side, and is sealed by a protective film 25. A sealing substrate 27 is bonded to the protective film 25 with an adhesive layer 26 that is formed of a thermosetting resin or an ultraviolet curable resin in between. The display unit 1 may be of a bottom emission type (a lower surface emission type) in which light generated in the organic layer 23 is extracted from the substrate 11 side, or a top emission type (an upper surface emission type) in which the light is extracted from the sealing substrate 27 side.

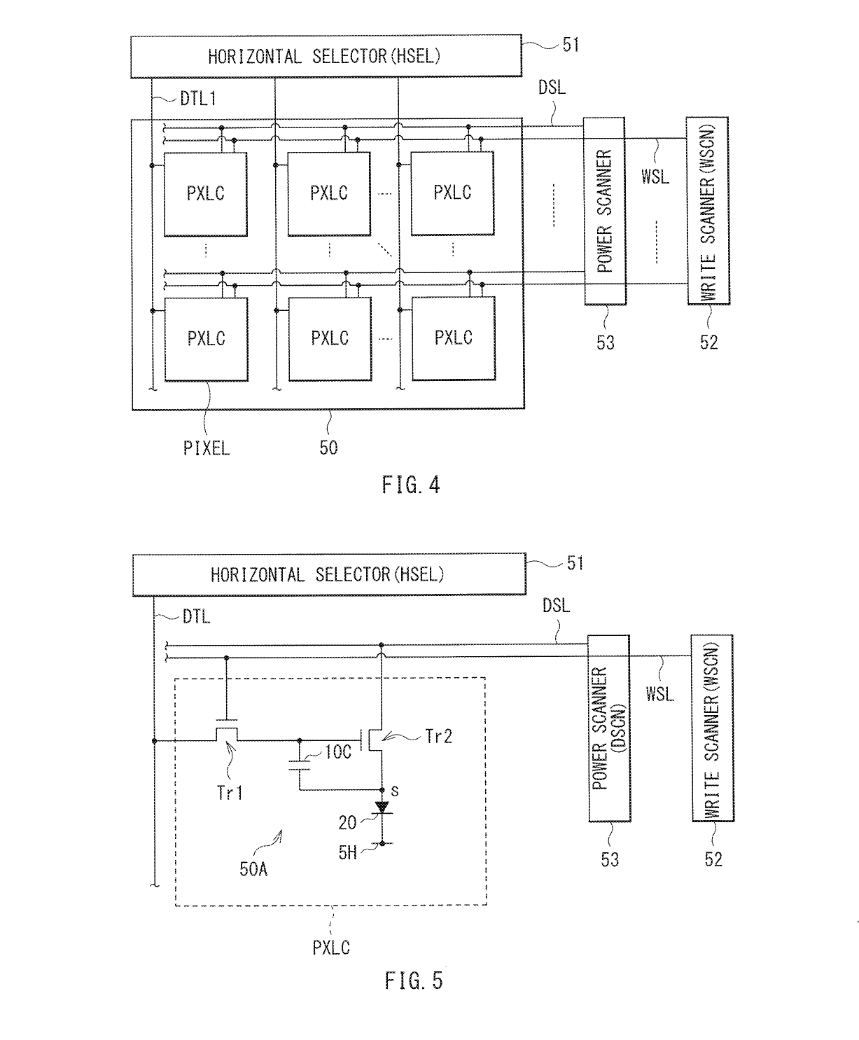

The planarization film 19 is provided over the entire display region (a display region 50 in FIG. 4 described later) of the substrate 11 on the source-drain electrode 18 and the interlayer insulating film 17, and has a connection hole H2. The connection hole H2 is used to connect the source-drain electrode 18 of the transistor 10T with the first electrode 21 of the organic EL element 20. The planarization film 19 may be formed of, for example, polyimide or an acrylic resin.

The first electrode 21 is provided on the planarization film 19 in such a manner as to fill the connection hole H2. The first electrode 21 may function as, for example, an anode, and is provided for each element. When the display unit 1 is of the bottom emission type, the first electrode 21 may be formed of a transparent conductive film, for example, a single layer film formed of any of indium tin oxide (ITO), indium zinc oxide (IZO), and the like, or a stacked-layer film formed of two or more thereof. On the other hand, when the display unit 1 is of the top emission type, the first electrode 21 may be formed of a reflective metal, for example, a simple metal formed of one or more of aluminum, magnesium (Mg), calcium (Ca), and sodium (Na), or a single layer film formed of an alloy containing one or more thereof, or a multilayer film configured by stacking simple metals or alloys.

The pixel separation film 22 secures insulation property between the first electrode 21 and the second electrode 24, and partitions and separates the light emission region of each element. The pixel separation film 22 has an opening opposed to the light emission region of each element. The pixel separation film 22 may be formed of, for example, a photosensitive resin such as polyimide, an acrylic resin, and a novolak resin.

The organic layer 23 is provided in such a manner as to cover the opening of the pixel separation film 22. The organic layer 23 includes an organic electroluminescence layer (an organic EL layer), and emits light in response to application of a drive current. For example, the organic layer 23 may have a hole injection layer, a hole transport layer, the organic EL layer, and an electron transport layer in this order from the substrate 11 (the first electrode 21) side, and light is emitted by recombination of electrons and holes in the organic EL layer. The material of the organic EL layer is a typical low-molecular or high-molecular organic material without specific limitation. For example, organic EL layers emitting red, green, and blue light are applied for each element, or an organic EL layer emitting white light (for example, configured by stacking organic EL layers of red, green, and blue) may be provided over the entire surface of the substrate 11. The hole injection layer enhances hole injection efficiency and prevents leakage, and the hole transport layer enhances hole transport efficiency to the organic EL layer. Layers other than the organic EL layer, namely, the hole injection layer, the hole transport layer, and the electron transport layer may be provided as necessary.

For example, the second electrode 24 may function as a cathode, and is configured of a metal conductive film. When the display unit 1 is of the bottom emission type, the second electrode 24 may be formed of a reflective metal, for example, a simple metal formed of one or more of aluminum, magnesium (Mg), calcium (Ca), and sodium (Na) or a single layer film formed of an alloy containing one or more thereof, or a multilayer film configured by stacking simple metals or alloys. On the other hand, when the display unit 1 is of the top emission type, a transparent conductive film such as ITO and IZO is used for the second electrode 24. The second electrode 24 is provided common to respective elements in a state of being insulated from the first electrode 21.

The protective film 25 may be formed of any of the insulating material and the conductive material. Examples of the insulating material may include, for example, amorphous silicon (a-Si), amorphous silicon carbide (a-SiC), amorphous silicon nitride (a-Si₍₁₋ₓ₎Nₓ), and amorphous carbon (a-C).

The sealing substrate 27 is disposed to face the substrate 11 with the transistor 10T, the retention capacitor 10C, and the organic EL element 20 in between. Materials similar to those of the above-described substrate 11 may be used for the sealing substrate 27. When the display unit 1 is of the top emission type, a transparent material is used for the sealing substrate 27, and a color filter or a light shielding film may be provided on the sealing substrate 27 side. When the display unit 1 is of the bottom emission type, the substrate 11 is formed of a transparent material, and a color filter or a light shielding film may be provided on the substrate 11 side.

### (Configuration of Peripheral Circuits and Pixel Circuit)

As illustrated in FIG. 4, the display unit 1 includes a plurality of pixels PXLC each including such an organic EL element 20, and the pixels PXLC may be arranged in, for example, a matrix in the display region 50 on the substrate 11. A horizontal selector (HSEL) 51 as a signal line drive circuit, a write scanner (WSCN) 52 as a scan line drive circuit, and a power scanner 53 as a power line drive circuit are provided on the periphery of the display region 50.

In the display region 50, a plurality of (the integer n-number of) signal lines DTL1 to DTLn are arranged in a column direction, and a plurality of (the integer m-number of) scan lines WSL1 to WSLm are arranged in a row direction. Each of the pixels PXLC (one of the pixels corresponding to R, G, and B) is provided at an intersection between each of the signal lines DTL and each of the scan lines WSL. Each of the signal lines DTL is electrically connected to the horizontal selector 51, and a picture signal is supplied from the horizontal selector 51 to the pixels PXLC through the respective signal lines DTL. On the other hand, each of the scan lines WSL is electrically connected to the write scanner 52, and a scan signal (a selection pulse) is supplied from the write scanner 52 to the pixels PXLC through the respective scan lines WSL. Each of power lines DSL is connected to the power scanner 53, and a power signal (a control pulse) is supplied from the power scanner 53 to the pixels PXLC through the respective power lines DSL.

FIG. 5 illustrates a specific example of a circuit configuration in the pixel PXLC. Each of the pixels PXLC has the pixel circuit 50A including the organic EL element 20. The pixel circuit 50A is an active drive circuit including a sampling transistor Tr1, a drive transistor Tr2, the retention capacitor 10C, and the organic EL element 20. One or both of the sampling transistor Tr1 and the drive transistor Tr2 correspond to the transistor 10T of the above-described embodiment.

A gate of the sampling transistor Tr1 is connected to a corresponding scan line WSL. One of a source and a drain of the sampling transistor Tr1 is connected to a corresponding signal line DTL, and the other is connected to a gate of the drive transistor Tr2. A drain of the drive transistor Tr2 is connected to a corresponding power line DSL, and a source thereof is connected to an anode of the organic EL element 20. In addition, a cathode of the organic EL element 20 is connected to a ground wiring 5H. Incidentally, the ground wiring 5H is wired commonly to all of the pixels PXLC. The retention capacitor 10C is disposed between the source and the gate of the drive transistor Tr2.

The sampling transistor Tr1 becomes conductive in response to the scan signal (the selection pulse) supplied from the scan line WSL to sample a signal potential of the picture signal supplied from the signal line DTL, thereby retaining the sampled signal potential in the retention capacitor 10C. The drive transistor Tr2 is supplied with a current from the power line DSL set at predetermined first potential (not illustrated), and supplies a drive current to the organic EL element 20 based on the signal potential retained in the retention capacitor 10C. The organic EL element 20 emits light with luminance corresponding to the signal potential of the picture signal, by the drive current supplied from the drive transistor Tr2.

In such a circuit configuration, the sampling transistor Tr1 becomes conductive in response to the scan signal (the selection pulse) supplied from the scan line WSL to sample the signal potential of the picture signal supplied from the signal line DTL, thereby retaining the sampled signal potential in the retention capacitor 10C. Moreover, the current is supplied from the power line DSL set at the above-described first potential to the drive transistor Tr2, and the drive current is supplied to the organic EL element 20 (each of the organic EL elements of red, green, and blue) based on the signal potential retained in the retention capacitor 10C. Then, each of the organic EL elements 20 emits light with luminance corresponding to the signal potential of the picture signal by the supplied drive current. As a result, picture display based on the picture signal is performed on the display unit 1.

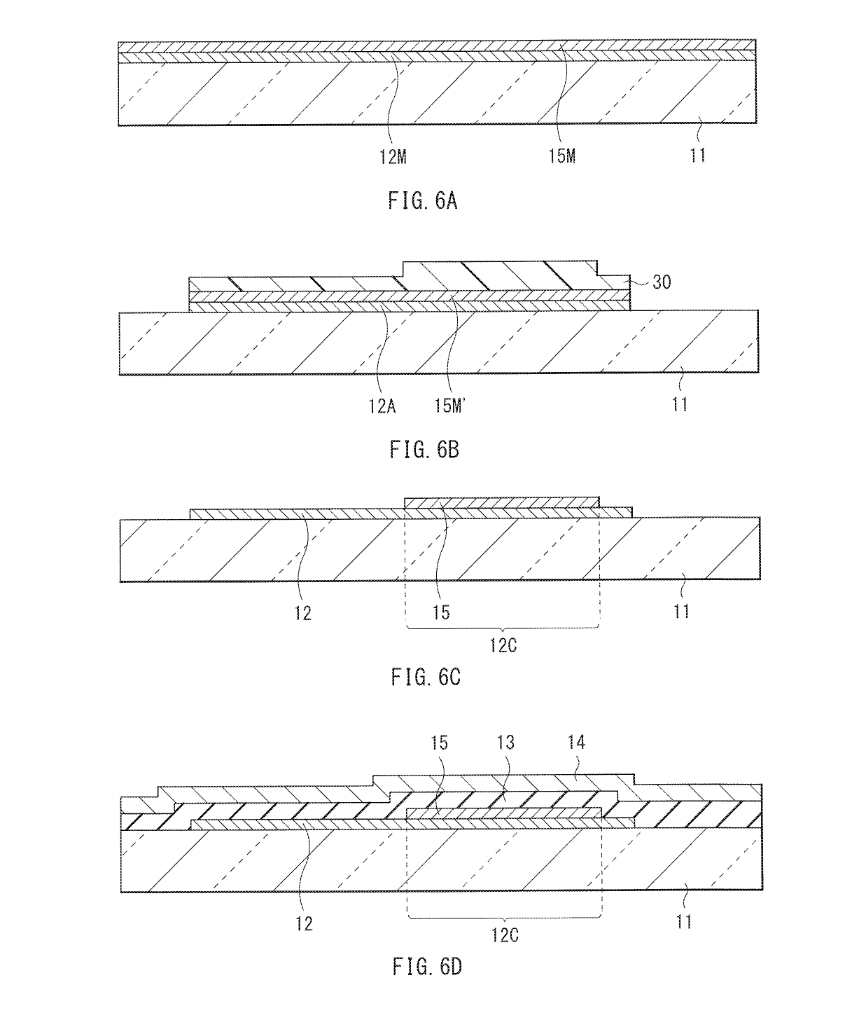

Such a display unit 1 may be manufactured, for example, in the following manner (FIG. 6A to FIG. 7C).

### (Process of Forming Transistor 10T and Retention Capacitor 10C)

First, as illustrated in FIG. 6A, a semiconductor material film 12M made of the material of the oxide semiconductor film 12 and an oxide conductive material film 15M made of the material of the oxide conductive film 15 are formed in this order on the entire surface of the substrate 11. For example, the semiconductor material film 12M and the oxide conductive material film 15M each may be formed to have the thickness of about 50 nm. The semiconductor material film 12M may be formed by, for example, a sputtering method. At this time, ceramic having the same composition as that of the oxide semiconductor to be formed is used as a target. Moreover, oxygen partial pressure is controlled to obtain desired transistor characteristics because carrier density in the oxide semiconductor largely depends on the oxygen partial pressure in the sputtering.

After the oxide conductive material film 15M is formed, as illustrated in FIG. 6B, a resist (a resist 30) whose film thickness is varied depending on the position in plane is formed on the oxide conductive material film 15M by, for example, photolithography using a half tone mask. In the resist 30, a thickness of a region where the oxide conductive film 15 is to be formed (a region including a region where the retention capacitor 10C is to be formed) is made larger than the thickness of other regions. Subsequently, for example, the semiconductor material film 12M may be etched with use of an etchant containing fluorine such as buffered hydrofluoric acid or oxalic acid, to form the oxide semiconductor film 12. The etchant (a first etchant) used in the etching process allows the oxide conductive material film 15M to be dissolved together with the semiconductor material film 12M. As a result, an oxide conductive material film 15M′ that has the same shape as that of the oxide semiconductor film 12M in a planner view is formed.

Subsequently, the entire surface of the resist 30 may be ashed by a dry etching apparatus or the like with use of, for example, oxygen gas to remove the resist 30 in a part where the film thickness is small. In other words, the region where the oxide conductive film 15 is to be formed is selectively covered with the resist 30. After that, wet etching may be performed with use of, for example, a mixed solution of phosphoric acid, nitric acid, and acetic acid to etch a part exposed from the resist 30 of the oxide conductive material film 15M′, and thus the oxide conductive film 15 is formed. At this time, an etchant (a second etchant) that allows only the material of the oxide conductive film 15 out of the material of the oxide semiconductor film 12 and the material of the oxide conductive film 15 to be dissolved is selected. As a result, the oxide conductive material film 15M′ out of the oxide semiconductor film 12 and the oxide conductive material film 15M′ is selectively etched. When the oxide semiconductor film 12 is formed of indium tin zinc oxide (ITZO), indium gallium oxide (IGO), indium tin oxide (ITO), aluminum tin zinc oxide (ATZO), or zinc tin oxide (ZTO) and the oxide conductive film 15 (the oxide conductive material film 15M′) is formed of indium gallium zinc oxide (IGZO) or indium zinc oxide (IZO (registered trademark)), the oxide conductive material film 15M′ is selectively etched by using the mixed solution of phosphoric acid, nitric acid, and acetic acid. When ITO is used for the oxide conductive film 15, it is difficult to selectively etch the oxide conductive material film 15M′ out of the oxide semiconductor film 12 and the oxide conductive material film 15M′. Since the dry etching may degrade the characteristics of the oxide semiconductor film 12, the oxide semiconductor film 12 and the oxide conductive film 15 may be preferably formed by wet etching.

After the oxide conductive film 15 is formed, the resist 30 is removed (FIG. 6C). Then, as illustrated in FIG. 6D, the insulating film 13 that is made of a silicon oxide film or an aluminum oxide film and has a thickness of about 200 nm and the conductive film 14 that is made of a metal material such as molybdenum, titanium, and aluminum and has a thickness of about 500 nm may be formed in this order over the entire surface of the substrate 11. For example, the insulating film 13 may be formed by a plasma CVD method. The insulating film 13 made of a silicon oxide film may be formed by a reactive sputtering method besides the plasma CVD method. Moreover, when an aluminum oxide film is used for the insulating film 13, an atomic layer deposition method may be used in addition to the reactive sputtering method and the CVD method described above. For example, the conductive film 14 may be formed by a sputtering method.

After the conductive film 14 is formed, the conductive film 14 may be patterned by, for example, photolithography and etching to form the gate electrode 14T and the capacitance electrode 14C in selective regions (the channel region 12T and the contact region 12C) on the oxide semiconductor film 12. Then, the insulating film 13 is etched with use of the gate electrode 14T and the capacitance electrode 14C as a mask. As a result, the gate insulating film 13T and the capacitance insulating film 13C are patterned into substantially the same shape as that of the gate electrode 14T and that of the capacitance electrode 14C, respectively, in a planar view (FIG. 7A). When the oxide semiconductor film 12 is made of the crystalline material such as indium gallium oxide and aluminum tin zinc oxide, the insulating film 13 is easily processed while the extremely-large etch selectivity is maintained, by using a chemical solution such as hydrofluoric acid in the etching process. The capacitance insulating film 13C and the capacitance electrode 14C of the retention capacitor 10C may be formed with use of a material different from that of the insulating film 13 and that of the conductive film 14 after formation of the gate electrode 14T and the gate insulating film 13T.

Subsequently, as illustrated in FIG. 7B, the metal film 16A that is made of, for example, titanium, aluminum, tin, or indium may be formed over the entire surface of the substrate 11 by, for example, the sputtering method so as to have a thickness of, for example, about 5 nm or more and about 10 nm or less. The metal film 16A is formed of a metal that reacts with oxygen at relatively low temperature so as to be in contact with a part of the oxide semiconductor film 12 other than a part formed with the gate electrode 14T and the capacitance electrode 14C. An insulating film (not illustrated) having high barrier property may be stacked on the metal film 16A after formation of the metal film 16A. As the insulating film, an aluminum oxide film having the thickness of, for example, about 50 nm may be formed by a sputtering method or an atomic layer deposition method.

Then, heat treatment is carried out at a temperature of, for example, about 200° C. under an oxygen atmosphere to oxidize the metal film 16A, and therefore the high-resistance film 16 made of a metal oxide film is formed. At this time, in the region other than the channel region 12T and the contact region 12C of the oxide semiconductor film 12, the low-resistance regions 12B (including the source-drain regions) are formed in parts on the high-resistance film 16 side in the thickness direction. Since part of oxygen contained in the oxide semiconductor film 12 is used in oxidation reaction of the metal film 16A, the oxygen concentration is lowered from a side of the surface (the top surface), which is in contact with the metal film 16A, of the oxide semiconductor film 12 along with progress of oxidation of the metal film 16A. On the other hand, a metal such as aluminum is diffused from the metal film 16A into the oxide semiconductor film 12. The metal element functions as dopant, and the region of the oxide semiconductor film 12 that is located on the top surface side and is in contact with the metal film 16A is decreased in resistance. Consequently, the low-resistance regions 12B each having electric resistance lower than the electric resistance of the channel region 12T and lower than the electric resistance of the contact region 12C are formed.

As the heat treatment of the metal film 16A, annealing at the temperature of about 200° C. may be preferable as described above. At that time, the annealing is performed under oxidized gas atmosphere containing oxygen and the like so that excess lowering of the oxygen concentration of the low-resistance regions 12B is suppressed, and sufficient amount of oxygen is allowed to be supplied to the oxide semiconductor film 12. Consequently, it is possible to eliminate the annealing performed in the subsequent process to simplify the process.

The high-resistance film 16 may be formed by setting the temperature of the substrate 11, at the time of forming the metal film 16A on the substrate 11, to relatively high, instead of the above-described annealing. For example, in the process of FIG. 7B, when the metal film 16A is formed while the temperature of the substrate 11 is maintained at about 200° C., a predetermined region of the oxide semiconductor film 12 is allowed to be decreased in resistance without carrying out the heat treatment. In this case, the carrier density of the oxide semiconductor film 12 is allowed to be reduced to a level necessary for a transistor.

The metal film 16A may be preferably formed to have a thickness of about 10 nm or less as described above. This is because when the thickness of the metal film 16A is equal to or less than about 10 nm, the metal film 16A is sufficiently oxidized (the high-resistance film 16 is formed) by heat treatment. If oxidation of the metal film 16A is insufficient, a process of removing unoxidized regions of the metal film 16A by etching is necessary. This is because if the insufficiently oxidized region of the metal film 16A is remained on the gate electrode 14T, the capacitance electrode 14C, and the like, a leakage current may occur. When the metal film 16A is sufficiently oxidized and the high-resistance film 16 is formed, such a removing process is unnecessary, and simplification of the manufacturing process becomes possible. In other words, occurrence of the leakage current is prevented without performing the removing process by etching. Note that when the metal film 16A is formed to have a thickness of about 10 nm or less, the thickness of the high-resistance film 16 that has been subjected to the heat treatment is about 20 nm or less.

As described above, it is preferable to form an insulating film with high barrier property such as an aluminum oxide film on the metal film 16A, and to form the high-resistance film 16 by the oxidized metal film 16A and the insulating film. In this way, the high-resistance film 16 has a sufficient protection function.

As a method of oxidizing the metal film 16A, methods such as oxidation in water-vapor atmosphere and plasma oxidation may be used in addition to the above-described heat treatment. In particular, using the plasma oxidation provides the following advantage. The interlayer insulating film 17 is formed by a plasma CVD method (FIG. 7C described later) after formation of the high-resistance film 16. At this time, the interlayer insulating film 17 may be formed subsequently (successively) after the metal film 16A is subjected to the plasma oxidation treatment. Therefore, advantageously, addition of the process is unnecessary. The plasma oxidation may be desirably performed by setting the temperature of the substrate 11 to about 200° C. to about 400° C. both inclusive and generating plasma in an oxygen-containing gas atmosphere such as mixed gas of oxygen and dinitrogen oxide. By such a process, the high-resistance film 16 having a function of reducing influence of oxygen and moisture is allowed to be formed.

Moreover, as a method of decreasing the resistance of the predetermined region of the oxide semiconductor film 12, a method in which the resistance is decreased by plasma treatment, a method in which a silicon nitride film is formed by the plasma CVD method and the resistance is decreased by hydrogen diffusion from the silicon nitride film or the like, may be used in addition to the above-described method using reaction between the metal film 16A and the oxide semiconductor film 12.

As illustrated in FIG. 7C, after formation of the high-resistance film 16, the interlayer insulating film 17 is formed over the entire surface of the high-resistance film 16. When the interlayer insulating film 17 contains an inorganic insulating material, for example, the plasma CVD method, the sputtering method, or the atomic layer deposition method may be used. When the interlayer insulating film 17 contains an organic insulating material, for example, coating methods such as a spin coating method and a slit coating method may be used. The thick interlayer insulating film 17 is allowed to be easily formed by the coating method. Subsequently, exposure and development are performed to form the connection hole H1 at a predetermined position of the interlayer insulating film 17. When a photosensitive resin is used for the interlayer insulating film 17, the exposure and the development are performed using the photosensitive resin so that the connection hole H1 is allowed to be formed at the predetermined position.

Subsequently, a conductive film (not illustrated) that is to be the source-drain electrode 18 made of the above-described material or the like may be formed on the interlayer insulating film 17 by, for example, the sputtering method, and the connection hole H1 is filled with the conductive film. After that, the conductive film may be patterned into a predetermined shape by, for example, photolithography and etching. As a result, the source-drain electrode 18 is formed on the interlayer insulating film 17, and the source-drain electrode 18 is electrically connected to the low-resistance region 12B of the oxide semiconductor film 12 through the connection hole H1.

### (Process of Forming Planarization Film 19)

After formation of the transistor 10T and the retention capacitor 10C in this way, the planarization film 19 made of the above-described material may be formed by, for example, the spin coating method or the slit coating method in such a manner as to cover the interlayer insulating film 17 and the source-drain electrode 18, and then the connection hole H2 is formed in a part of a region of the planarization film 19 facing the source-drain electrode 18.

### (Process of Forming Organic EL Element 20)

Subsequently, the organic EL element 20 is formed on the planarization film 19. Specifically, the first electrode 21 made of the above-described material may be formed on the planarization film 19 by, for example, the sputtering method in such a manner as to fill the connection hole H2. Then, patterning is performed by the photolithography and the etching. Thereafter, after the pixel separation film 22 having an opening is formed on the first electrode 21, the organic layer 23 may be formed by, for example, a vacuum deposition method. Subsequently, the second electrode 24 made of the above-described material may be formed on the organic layer 23 by, for example, the sputtering method. Then, after the protective film 25 may be formed on the second electrode 24 by, for example, the CVD method, the sealing substrate 27 is bonded to the protective film 25 with use of the adhesive layer 26. The display unit 1 illustrated in FIG. 1 is completed by the above-described processes.

In the display unit 1, for example, when each of the pixels PXLC corresponding to any of R, G, and B is supplied with a drive current corresponding to a picture signal of each color, electrons and holes are injected into the organic layer 23 through the first electrode 21 and the second electrode 24. These electrons and holes are recombined in the organic EL layer included in the organic layer 23 to emit light. In this way, in the display unit 1, a full color picture of, for example, R, G, and B may be displayed. In addition, when potential corresponding to the picture signal is applied to one end of the retention capacitor 10C at the time of picture display operation, charges corresponding to the picture signal are accumulated between the oxide conductive film 15 and the capacitance electrode 14C.

In this case, the oxide conductive film 15 on the oxide semiconductor film 12 is formed of the oxide conductive material. Therefore, oxygen in the oxide semiconductor film 12 is difficult to migrate to the oxide conductive film 15, and degradation of transfer characteristics of the transistor 10T is allowed to be suppressed. This will be described in detail below.

In the display unit in which the oxide semiconductor film is shared by the transistor and the retention capacitor, a method in which a metal film made of titanium, molybdenum, aluminum, or the like is formed separately from the oxide semiconductor film, in a formation region of the retention capacitor, in order to suppress voltage dependency of the capacitance of the retention capacitor has been proposed (for example, see Japanese Unexamined Patent Application Publication No. 2012-212077). However, since the metal film is provided in such a manner as to be in contact with the oxide semiconductor film, the metal film easily influences the oxide semiconductor film. Specifically, oxygen in the oxide semiconductor film may migrate to the metal film and thus oxygen omission occurs in the oxide semiconductor film, which may degrade the transfer characteristics of the transistor.

In contrast, in the display unit 1, the oxide conductive film 15 that is previously put into an oxidized state is used as one of electrodes of the retention capacitor 10C. Therefore, the oxide conductive film 15 is difficult to be oxidized, and migration of oxygen from the oxide semiconductor film 12 to the oxide conductive film 15 is difficult to occur. As a result, it is possible to prevent oxygen omission in the oxide semiconductor film 12, and to suppress degradation of the transfer characteristics of the transistor 10T.

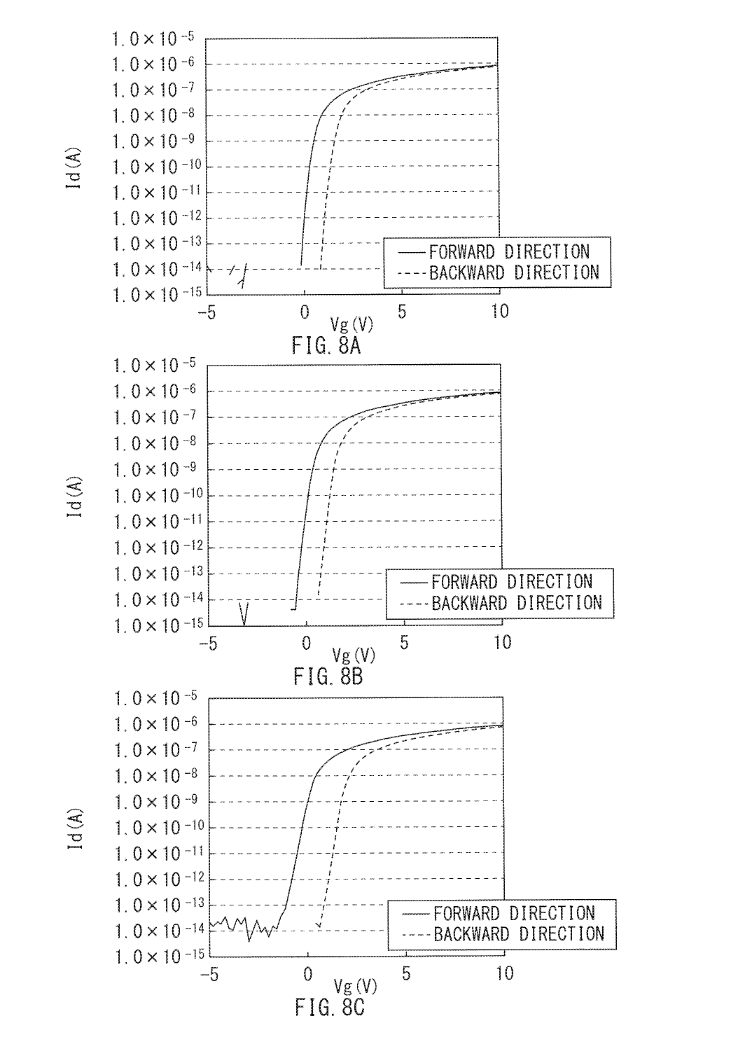

FIGS. 8A, 8B, and 8C each illustrate hysteresis of transfer characteristics of a transistor in a display unit. The display unit of FIG. 8A was not provided with a metal film and an oxide conductive film in a formation region of a retention capacitor. The display unit of FIG. 8B was provided with an oxide conductive film made of indium gallium zinc oxide (IGZO) having a thickness of about 80 nm, and the display unit of FIG. 8C was provided with a metal film formed of molybdenum. In the display units of FIGS. 8A, 8B, and 8C, indium tin zinc oxide (ITZO) having a thickness of about 20 nm was used for the oxide semiconductor film. As compared with FIG. 8A, the transfer characteristics were largely deviated between a forward direction and a backward direction in FIG. 8C, whereas deviation of the transfer characteristics in FIG. 8B was small and was the same level with FIG. 8A. In this way, in the display unit 1 having the oxide conductive film 15, it was confirmed that the transfer characteristics of the transistor 10T were maintained.

Further, if the metal element migrates from the oxide conductive film 15 to the oxide semiconductor film 12, it is possible to lower the influence by using the material having one or more of the metal elements same as the materials of the oxide semiconductor film 12 as the material of the oxide conductive film 15.

In the display unit 1, it was confirmed that providing the oxide conductive film 15 suppressed voltage dependency of the retention capacitor 10C, similarly to the case where the metal film was provided.

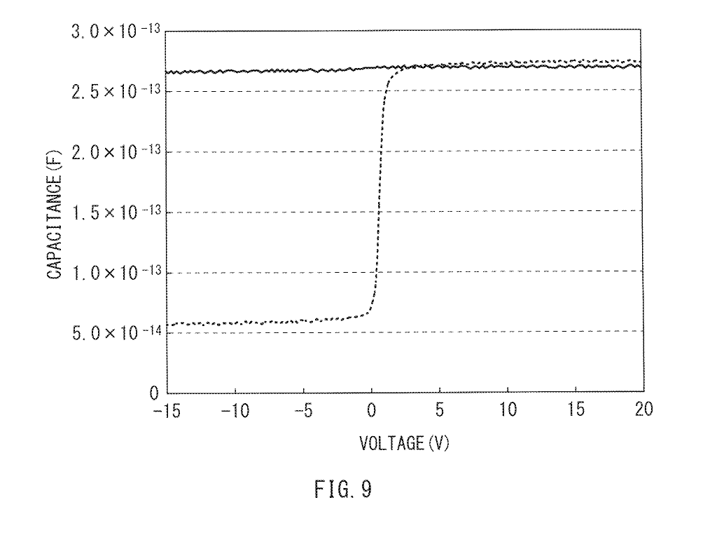

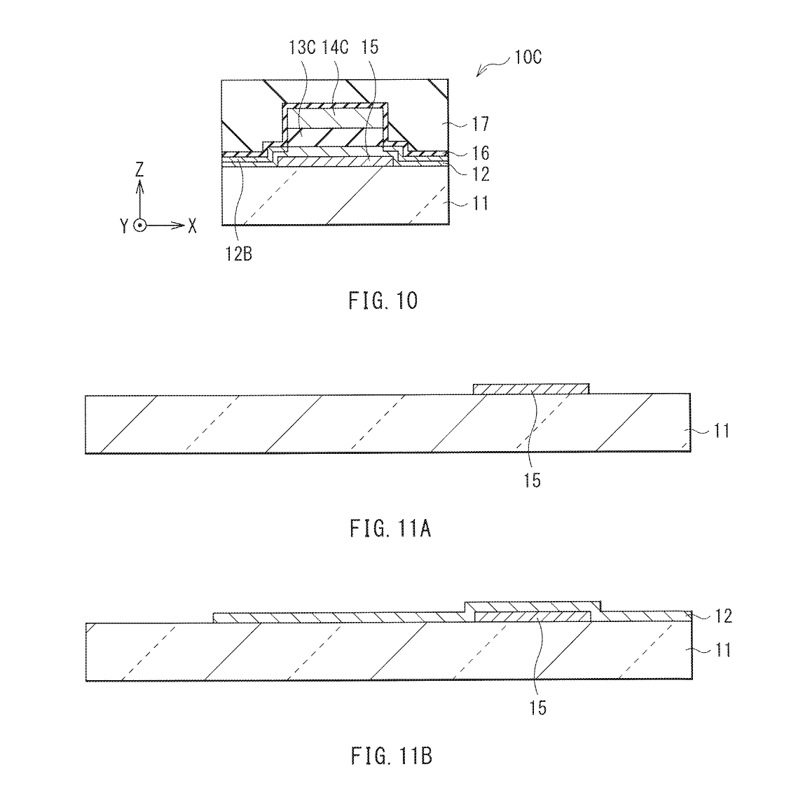

A solid line in FIG. 9 indicates a result obtained by measuring the retention capacitance (F) of the retention capacitor 10C provided with the oxide conductive film 15 made of indium gallium zinc oxide (IGZO) while varying the magnitude of the applied voltage (V). Indium tin zinc oxide (ITZO) was used for the oxide semiconductor film 12. A dashed line in FIG. 9 indicates the retention capacitance (F) of a retention capacitor in which an oxide conductive film was not provided and indium tin zinc oxide was used as one of the electrodes. In this way, it was confirmed that the oxide conductive film 15 functioned similarly to the metal film, and in the retention capacitor 10C, a desired capacitance was allowed to be retained irrespective of the magnitude of the applied voltage.

Moreover, forming the oxide conductive film 15 on the oxide semiconductor film 12 makes it possible to form the oxide semiconductor film 12 and the oxide conductive film 15 in a single photolithography process as described above. This will be described below.

As illustrated in FIG. 10, the oxide semiconductor film 12 may be provided between the oxide conductive film 15 and the capacitance electrode 14C. In the retention capacitor 10C with such a structure, after the oxide conductive film 15 is formed in the region where the retention capacitor 10C is to be formed (FIG. 11A), the oxide semiconductor film 12 extending the region where the transistor 10T is to be formed and the region where the retention capacitor 10C is to be formed, is formed on the oxide conductive film 15 (FIG. 11B). Accordingly, the photolithography process is necessary in each of the formation process of the oxide conductive film 15 and the formation process of the oxide semiconductor film 12.

On the other hand, when the oxide conductive film 15 is formed in a selective region on the oxide semiconductor film 12, the oxide semiconductor film 12 and the oxide conductive film 15 are formed in a single photolithography process by using a half tone mask or the like.

As described above, in the present embodiment, the oxide conductive film 15 containing the oxide material is provided as one of the electrodes of the retention capacitor 10C. Therefore, it is possible to retain a desired capacitance stably in the retention capacitor 10C, and to suppress degradation of the transfer characteristics of the transistor 10T. As a result, in the display unit 1, it is possible to improve display quality.

Moreover, forming the oxide conductive film 15 on the oxide semiconductor film 12 reduces the number of photolithography processes, which makes it possible to suppress cost.

Further, the low-resistance regions 12B are provided in the oxide semiconductor film 12 to allow the transistor 10T to have a so-called self-alignment structure. Therefore, it is possible to reduce parasitic capacitance.

Hereinafter, modifications of the present embodiment will be described. In the following description, like numerals are used to designate substantially like components of the above-described embodiment and the description thereof is appropriately omitted.

### <Modification 1>

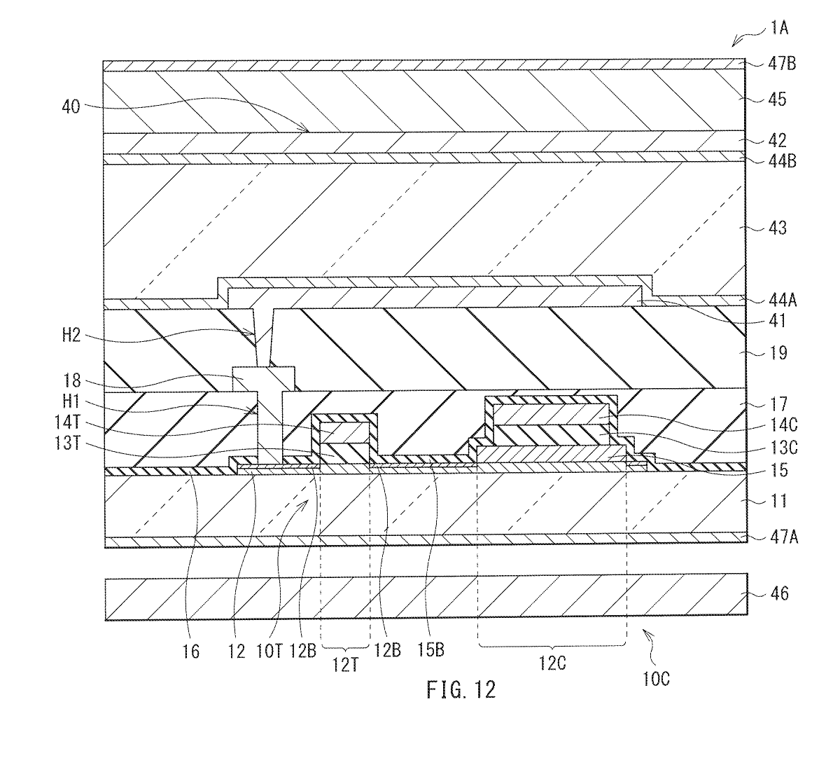

FIG. 12 illustrates a sectional structure of a display unit (a display unit 1A) according to a modification 1 of the above-described embodiment. The display unit 1A has a liquid crystal display element 40 in place of the organic EL element 20 of the display unit 1. Except for this point, the display unit 1A has the similar structure to that of the display unit 1 of the above-described embodiment, and has similar function and effects.

The display unit 1A has the transistor 10T and the retention capacitor 10C similar to those of the display unit 1, and the liquid crystal display element 40 is provided in a layer above the transistor 10T and the retention capacitor 10C with the planarization film 19 in between.

The liquid crystal display element 40 may be configured by, for example, sealing a liquid crystal layer 43 between a pixel electrode 41 and a counter electrode 42. An alignment film 44A is provided on a surface on the liquid crystal layer 43 side of the pixel electrode 41, and an alignment film 44B is provided on a surface on the liquid crystal layer 43 side of the counter electrode 42. The pixel electrode 41 is provided for each pixel, and may be electrically connected to the source-drain electrode 18 of the transistor 10T, for example. The counter electrode 42 is provided on the counter substrate 45 as an electrode common to the plurality of pixels, and may be maintained at, for example, common potential. The liquid crystal layer 43 may be configured of a liquid crystal driven by, for example, vertical alignment (VA) mode, twisted nematic (TN) mode, in plane switching (IPS) mode, or the like.

Moreover, a backlight 46 is provided below the substrate 11, a polarization plate 47A is bonded to a surface on the backlight 46 side of the substrate 11, and a polarization plate 47B is bonded to a surface of the counter substrate 45.

The backlight 46 is a light source emitting light toward the liquid crystal layer 43, and includes a plurality of light emitting diodes (LEDs), a plurality of cold cathode fluorescent lamps (CCFLs), or the like. Light emission state and light extinction state of the backlight 46 are controlled by a backlight drive section (not illustrated).

The polarization plates 47A and 47B (polarizer or analyzer) may be disposed, for example, in crossed-Nicols with each other, and for example, this may allow illumination light from the backlight 46 to be blocked in a no-voltage applied state (off state), and to pass therethrough in a voltage applied state (on state).

In the display unit 1A, similarly to the display unit 1 of the above-described embodiment, the oxide conductive film 15 contains the oxide material. Therefore, oxygen is difficult to migrate from the oxide semiconductor film 12 to the oxide conductive film 15. Accordingly, also in the present modification, it is possible to suppress degradation of the transfer characteristics of the transistor 10T.

### <Modification 2>

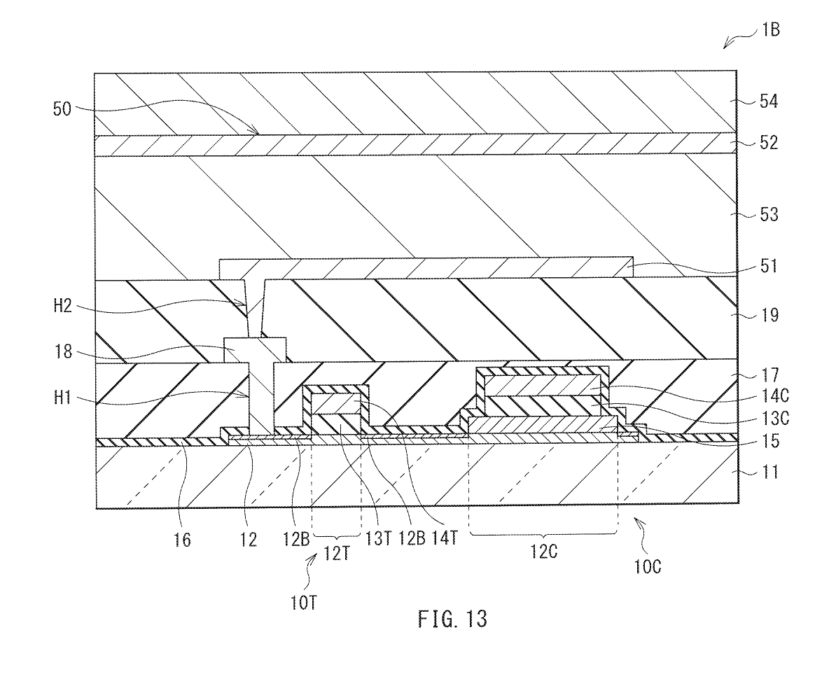

FIG. 13 illustrates a sectional structure of a display unit (a display unit 1B) according to a modification 2 of the above-described embodiment. The display unit 1B is a so-called electronic paper, and has an electrophoretic display element 50 in place of the organic EL element 20 of the display unit 1. Except for this point, the display unit 1B has the similar structure to that of the display unit 1 of the above-described embodiment, and has similar function and effects.

The display unit 1B has the transistor 10T and the retention capacitor 10C similar to those of the display unit 1, and the electrophoretic display element 50 is provided in a layer above the transistor 10T and the retention capacitor 10C with the planarization film 19 in between.

The electrophoretic display element 50 may be configured by, for example, sealing a display layer 53 made of an electrophoretic display substance between a pixel electrode 51 and a common electrode 52. The pixel electrode 51 is provided for each pixel, and may be electrically connected to the source-drain electrode 18 of the transistor 10T, for example. The common electrode 52 is provided on a counter substrate 54 as an electrode common to the plurality of pixels.

In the display unit 1B, similarly to the display unit 1 of the above-described embodiment, the oxide conductive film 15 contains the oxide material. Therefore, oxygen is difficult to migrate from the oxide semiconductor film 12 to the oxide conductive film 15. Accordingly, also in the present modification, it is possible to suppress degradation of the transfer characteristics of the transistor 10T.

### Application Examples

Hereinafter, application examples of the above-described display units (the display units 1, 1A, and 1B) to electronic apparatuses will be described. Examples of the electronic apparatuses may include, without limitation, a television and a smartphone. In addition, any of the above-described display units is applicable to electronic apparatuses in various fields that display an externally input picture signal or an internally generated picture signal as an image or a picture.

### (Module)

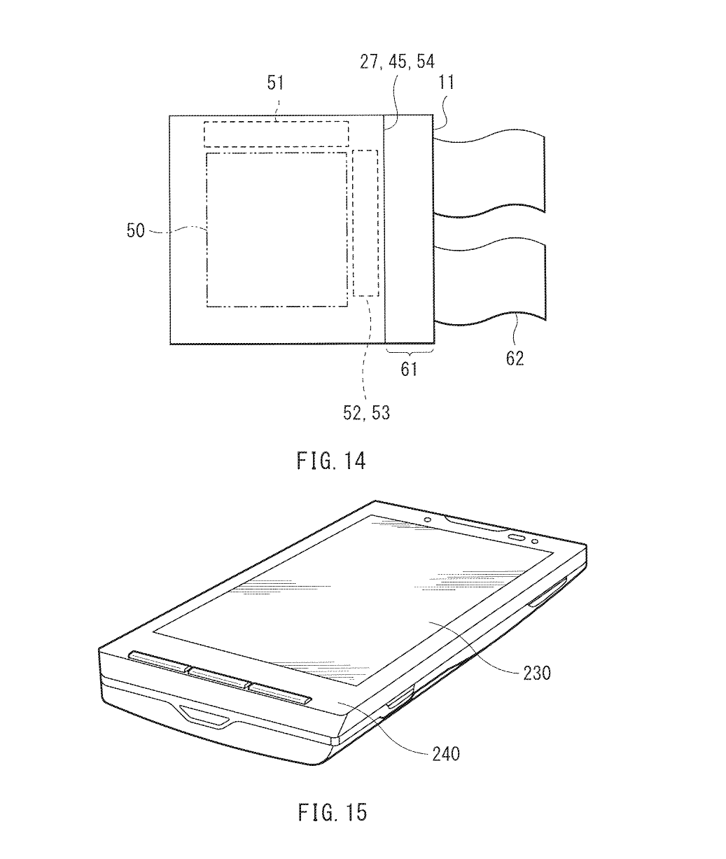

Any of the above-described display units is incorporated in various kinds of electronic apparatuses such as electronic apparatuses according to application examples 1 and 2 described below, as a module illustrated in FIG. 14, for example. In the module, for example, a region 61 that is exposed from the sealing substrate 27 or the counter substrate 45 or 54 is provided on one side of the substrate 11, and wirings of the horizontal selector 51, the write scanner 52, and the power scanner 53 are extended to configure an external connection terminal (not illustrated) in the exposed region 61. The external connection terminal may be provided with a flexible printed circuit (FPC) 62 for inputting and outputting signals.

### Application Example 1

FIG. 15 illustrates an appearance of a smartphone to which the display unit according to the above-described embodiment is applied. The smartphone may include, for example, a display section 230 and a non-display section 240, and the display section 230 is configured of the display unit according to the above-described embodiment.

### Application Example 2

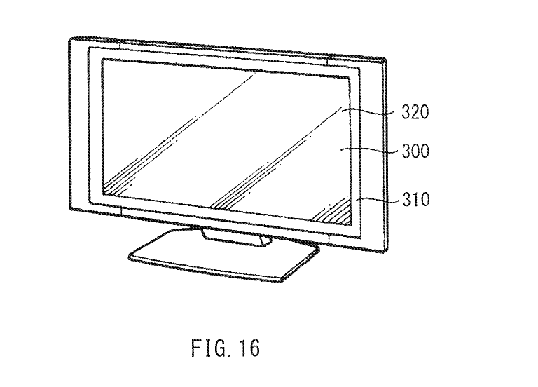

FIG. 16 illustrates an appearance of a television to which the display unit according to the above-described embodiment is applied. The television may include, for example, a picture display screen section 300 including a front panel 310 and a filter glass 320, and the picture display screen section 300 is configured of the display unit according to the above-described embodiment.

Hereinbefore, although the technology has been described with reference to the embodiment and the modifications, the technology is not limited to the embodiment and the like, and various modifications may be made. For example, the case where the oxide semiconductor film 12 and the oxide conductive film 15 are formed in a single photolithography process has been described with reference to FIG. 6B. However, a photolithography process may be performed for each of the oxide semiconductor film 12 and the oxide conductive film 15. Moreover, in the above-described embodiment and the like, the etchant allowing the material of the oxide semiconductor film 12 and the material of the oxide conductive film 12 to be dissolved, and the etchant allowing the material of the oxide conductive film 15 out of the material of the oxide semiconductor film 12 and the material of the oxide conductive film 15 to be dissolved have been exemplified. However, any etchant may be used as long as the etchant is allowed to pattern the oxide semiconductor film 12 and the oxide conductive film 15.

Moreover, in the above-described embodiment and the like, the structure including the high-resistance film 16 has been described as an example. However, the high-resistance film 16 may be removed after formation of the low-resistance regions 12B. Incidentally, as described above, the high-resistance film 16 is desirably provided because the electrical characteristics of the transistor 10T and the retention capacitor 10C are maintained stably.

Moreover, in the above-described embodiment and the like, the case where the low-resistance region 12B is provided in a part of the thickness direction from the surface (the top surface) of the region other than the channel region 12C of the oxide semiconductor film 12 has been described. However, the low-resistance region 12B may be provided in the entire part of the thickness direction from the surface (the top surface) of the oxide semiconductor film 12.

Moreover, the material and the thickness of each of the layers and the film formation method and the film formation condition described in the above-described embodiment and the like are not limited and other materials and other thicknesses or other film formation methods and other film formation conditions may be used.

Furthermore, in the above-described embodiment and the like, the configuration of each of the organic EL element 20, the liquid crystal display element 40, the electrophoretic display element 50, the transistor 10T, and the retention capacitor 10C has been described specifically. However, all of the layers are not necessarily provided, and other layers may be further provided.

In addition, the technology is applicable to a display unit using other display elements such as an inorganic electroluminescence element, besides the organic EL element 20, the liquid crystal display element 40, and the electrophoretic display element 50.

Furthermore, for example, the structure of the display unit has been specifically described in the above-described embodiment. However, all of the components are not necessarily provided, and other components may be further provided.

Moreover, in the above-described embodiment and the like, the display unit has described as an example of a semiconductor device provided with the transistor 10T and the retention capacitor 10C. However, the semiconductor device is applicable to an image detector or the like.

Note that the effects described in the present specification are illustrative and non-limiting. Effects achieved by the technology may be effects other than those described above.

Note that the present technology may be configured as follows.

(1) A semiconductor device including:

a transistor having an oxide semiconductor film; and

a retention capacitor having a first conductive film and a second conductive film, the first conductive film containing an oxide material and being in contact with the oxide semiconductor film, and the second conductive film facing the first conductive film with an insulating film in between.

(2) The semiconductor device according to (1), wherein a surface of the first conductive film opposite to a surface facing the second conductive film is in contact with the oxide semiconductor film.

(3) The semiconductor device according to (1) or (2), wherein the oxide semiconductor film exhibits higher etching resistance to a predetermined etchant than the first conductive film.

(4) The semiconductor device according to any one of (1) to (3), wherein the oxide material contains at least one metal element same as a metal element belonging to a material structuring the oxide semiconductor film.

(5) The semiconductor device according to any one of (1) to (4), wherein

the oxide semiconductor film contains one or more of indium tin zinc oxide, indium gallium oxide, indium tin oxide, aluminum tin zinc oxide, and zinc tin oxide, and

the first conductive film contains one or both of indium gallium zinc oxide and zinc indium oxide.

(6) The semiconductor device according to any one of (1) to (5), wherein

the transistor and the retention capacitor are provided on a substrate, and

the transistor includes the oxide semiconductor film, a gate insulating film, and a gate electrode in this order on the substrate.

(7) The semiconductor device according to (6), wherein the retention capacitor includes the first conductive film, the insulating film, and the second conductive film in this order on the substrate.

(8) The semiconductor device according to (7), wherein

the oxide semiconductor film is provided over a formation region of the transistor and a formation region of the retention capacitor, and

the first conductive film is provided on the oxide semiconductor film.

(9) The semiconductor device according to (6), wherein the oxide semiconductor film includes a channel region and a pair of low-resistance regions, the channel region being provided at a position facing the gate electrode, and the pair of low-resistance regions being provided at positions adjacent to the channel region.

(10) The semiconductor device according to (9), further including a high-resistance film in contact with the low-resistance regions of the oxide semiconductor film.

(11) The semiconductor device according to (10), wherein the high-resistance film contains a metal oxide.

(12) The semiconductor device according to (9), wherein the transistor includes a source-drain electrode electrically connected to the low-resistance region of the oxide semiconductor film.

(13) The semiconductor device according to (6), wherein

the gate insulating film of the transistor and the insulating film of the retention capacitor have a same thickness and are formed of a same material as each other, and

the gate electrode of the transistor and the second conductive film of the retention capacitor have a same thickness and are formed of a same material as each other.

(14) A display unit provided with a plurality of display elements and a semiconductor device configured to drive the display elements, the semiconductor device including:

a transistor having an oxide semiconductor film; and

a retention capacitor having a first conductive film and a second conductive film, the first conductive film containing an oxide material and being in contact with the oxide semiconductor film, and the second conductive film facing the first conductive film with an insulating film in between.

(15) An electronic apparatus provided with a display unit, the display unit being provided with a plurality of display elements and a semiconductor device configured to drive the display elements, the semiconductor device including:

a transistor having an oxide semiconductor film; and

a retention capacitor having a first conductive film and a second conductive film, the first conductive film containing an oxide material and being in contact with the oxide semiconductor film, and the second conductive film facing the first conductive film with an insulating film in between.

(16) A method of manufacturing a semiconductor device, the method including:

forming an oxide semiconductor film;

forming a first conductive film, the first conductive film being in contact with the oxide semiconductor film and containing an oxide material;

and forming a transistor and a retention capacitor having the first conductive film and a second conductive film, the transistor having a channel region provided in a part of the oxide semiconductor film, and the second conductive film facing the first conductive film with an insulating film in between.

(17) The method according to (16), wherein the first conductive film is formed in a selective region on the oxide semiconductor film.

(18) The method according to (17), wherein the oxide semiconductor film and the first conductive film are formed in a single photolithography process by using a half tone mask.

(19) The method according to (18), wherein

a first etchant allowing a material of the oxide semiconductor film and a material of the first conductive film to be dissolved is used in the formation of the oxide semiconductor film, and

a second etchant allowing the material of the first conductive film out of the material of the oxide semiconductor film and the material of the first conductive film to be dissolved is used in the formation of the first conductive film.

(20) The method according to (19), wherein

one of buffered hydrofluoric acid and oxalic acid is used as the first etchant, and

a mixed solution of phosphoric acid, nitric acid, and acetic acid is used as the second etchant.

It should be understood by those skilled in the art that various modifications, combinations, sub-combinations, and alterations may occur depending on design requirements and other factors insofar as they are within the scope of the appended claims or the equivalents thereof.

What is claimed is:

1. A semiconductor device comprising:
a transistor having an oxide semiconductor film; and
a retention capacitor having a first conductive film and a second conductive film, the first conductive film containing an oxide material and being in contact with the oxide semiconductor film, and the second conductive film facing the first conductive film with an insulating film in between.

2. The semiconductor device according to claim 1, wherein a surface of the first conductive film opposite to a surface facing the second conductive film is in contact with the oxide semiconductor film.

3. The semiconductor device according to claim 1, wherein the oxide semiconductor film exhibits higher etching resistance to a predetermined etchant than the first conductive film.

4. The semiconductor device according to claim 1, wherein the oxide material contains at least one metal element same as a metal element belonging to a material structuring the oxide semiconductor film.

5. The semiconductor device according to claim 1, wherein
the oxide semiconductor film contains one or more of indium tin zinc oxide, indium gallium oxide, indium tin oxide, aluminum tin zinc oxide, and zinc tin oxide, and
the first conductive film contains one or both of indium gallium zinc oxide and zinc indium oxide.

6. The semiconductor device according to claim 1, wherein
the transistor and the retention capacitor are provided on a substrate, and
the transistor includes the oxide semiconductor film, a gate insulating film, and a gate electrode in this order on the substrate.

7. The semiconductor device according to claim 6, wherein the retention capacitor includes the first conductive film, the insulating film, and the second conductive film in this order on the substrate.

8. The semiconductor device according to claim 7, wherein
the oxide semiconductor film is provided over a formation region of the transistor and a formation region of the retention capacitor, and
the first conductive film is provided on the oxide semiconductor film.

9. The semiconductor device according to claim 6, wherein the oxide semiconductor film includes a channel region and a pair of low-resistance regions, the channel region being provided at a position facing the gate electrode, and the pair of low-resistance regions being provided at positions adjacent to the channel region.

10. The semiconductor device according to claim 9, further comprising a high-resistance film in contact with the low-resistance regions of the oxide semiconductor film.

11. The semiconductor device according to claim 10, wherein the high-resistance film contains a metal oxide.

12. The semiconductor device according to claim 9, wherein the transistor includes a source-drain electrode electrically connected to the low-resistance region of the oxide semiconductor film.

13. The semiconductor device according to claim 6, wherein
the gate insulating film of the transistor and the insulating film of the retention capacitor have a same thickness and are formed of a same material as each other, and
the gate electrode of the transistor and the second conductive film of the retention capacitor have a same thickness and are formed of a same material as each other.

14. A display unit provided with a plurality of display elements and a semiconductor device configured to drive the display elements, the semiconductor device comprising:
a transistor having an oxide semiconductor film; and
a retention capacitor having a first conductive film and a second conductive film, the first conductive film containing an oxide material and being in contact with the oxide semiconductor film, and the second conductive film facing the first conductive film with an insulating film in between.

15. An electronic apparatus provided with a display unit, the display unit being provided with a plurality of display elements and a semiconductor device configured to drive the display elements, the semiconductor device comprising:
a transistor having an oxide semiconductor film; and
a retention capacitor having a first conductive film and a second conductive film, the first conductive film containing an oxide material and being in contact with the oxide semiconductor film, and the second conductive film facing the first conductive film with an insulating film in between.

16. A method of manufacturing a semiconductor device, the method comprising:
forming an oxide semiconductor film;
forming a first conductive film, the first conductive film being in contact with the oxide semiconductor film and containing an oxide material; and
forming a transistor and a retention capacitor having the first conductive film and a second conductive film, the transistor having a channel region provided in a part of the oxide semiconductor film, and the second conductive film facing the first conductive film with an insulating film in between.

17. The method according to claim 16, wherein the first conductive film is formed in a selective region on the oxide semiconductor film.

18. The method according to claim 17, wherein the oxide semiconductor film and the first conductive film are formed in a single photolithography process by using a half tone mask.

19. The method according to claim 18, wherein
a first etchant allowing a material of the oxide semiconductor film and a material of the first conductive film to be dissolved is used in the formation of the oxide semiconductor film, and
a second etchant allowing the material of the first conductive film out of the material of the oxide semiconductor film and the material of the first conductive film to be dissolved is used in the formation of the first conductive film.

20. The method according to claim 19, wherein
one of buffered hydrofluoric acid and oxalic acid is used as the first etchant, and
a mixed solution of phosphoric acid, nitric acid, and acetic acid is used as the second etchant.
